(19) United States
(12) Patent Application Publication
(10) Pub. No.: US 2025/0029891 A1
(43) Pub. Date: Jan. 23, 2025

(54) INTEGRATED CIRCUIT SYSTEMS COOLED BY EMBEDDED MICROTUBES

(71) Applicants: SABANCI UNIVERSITESI, Istanbul (TR); SABANCI UNIVERSITESI NANOTEKNOLOJI ARASTIRMA VE UYGULAMA MERKEZI SUNUM, Istanbul (TR)

(72) Inventors: Murat Kaya YAPICI, Istanbul (TR); Ali KOSAR, Istanbul (TR); Abdolali Khalili SADAGHIANI, Istanbul (TR); Farid Sayar IRANI, Istanbul (TR); Soroush NIAZI, Istanbul (TR)

(73) Assignees: SABANCI UNIVERSITESI, Istanbul (TR); SABANCI UNIVERSITESI NANOTEKNOLOJI ARASTIRMA VE UYGULAMA MERKEZI SUNUM, Istanbul (TR)

(21) Appl. No.: 18/713,734

(22) PCT Filed: Dec. 29, 2022
(86) PCT No.: PCT/TR2022/051685

§ 371 Date: May 28, 2024

(30) Foreign Application Priority Data
Dec. 31, 2021 (TR) 2021/022036

(51) Int. Cl. H01L 23/473; H01L 21/306; H01L 23/31; H01L 25/065

(52) U.S. Cl. CPC H01L 23/473; H01L 23/3178; H01L 25/0657; H01L 21/306; H01L 2225/06589

(57) ABSTRACT

An integrated circuit unit comprises at least one electronic chip consisting of a wafer body including at least one groove extending along its surface from one end to the other, and of an active area; the integrated circuit unit further comprises at least one tube, which is housed in the groove therein, and which allows the transport of a fluid for cooling the electronic chips. A three-dimensional stack-type integrated circuit system comprises two integrated circuit units and a three-dimensional stack-type integrated circuit system comprising more than two integrated circuit units.

### CROSS REFERENCE TO RELATED APPLICATIONS

This application is a national stage entry of International Application No. PCT/TR2022/051685, filed on Dec. 29, 2022, which is based upon and claims foreign priority to Turkey Patent Application No. TR2021/022036, filed on Dec. 31, 2021, the entire contents of which are incorporated herein by reference.

### TECHNICAL FIELD

The present invention relates to integrated circuit systems comprising a cooling element for removing heat from the environment. The present invention relates to a cooling technology based on liquid flow, that can be directly integrated into either a single integrated circuit unit, or three-dimensional stack-type integrated circuit systems that require a greater heat dissipation. In this regard, the present invention relates to the direct use of the cooling elements that allow a fluid to pass therethrough, by integrating them with the integrated circuit unit or three-dimensional stack-type integrated circuit systems.

### BACKGROUND

Every year, electronic devices are becoming more and more important in daily life. The integrated circuits in electronic devices, whose structures are becoming more and more complex, are expected to meet the ever-increasing performance needs. It is required that said integrated circuit systems are compact, high-speed and multifunctional.

Integrated circuits are used in many electronic applications such as computers, mobile phones, digital cameras, etc. Integrated circuits are generally created by placing an active area on a semiconductor body and then adding the desired circuit components on the active area. Integrated circuits generate heat during operation. If the heat raises the temperature of the device above a certain critical level, the electrical properties of the material are adversely affected and thus the properties of the device may change. Thus, the performance of the device decreases and even malfunctions may occur.

On the other hand, in order to increase the performance of the integrated circuits and reduce their power consumption, it is preferred that the integrated circuit systems and the elements thereof are reduced in size and are lighter. In addition, due to the fact that electronic devices find more use in daily life, the need for small-sized electronic devices is gradually increasing. Due to the reduced size of the integrated circuits, many tasks are performed at high speeds, which inevitably results in the generation of excessively high heat.

In addition, as said integrated circuits get smaller, a dense number of interconnections are used to connect these circuits to large electronic devices. The density of the connection circuits creates an obstacle to the removal of heat from the integrated circuit and even causes an increase in the heat produced by the electronic device. For example, in order to increase the power of electronic devices, a higher number of transistors have been incorporated into each chip. However, since each component emits heat while performing its function, the resulting heat increases rapidly as the distance between the components decreases.

One of the alternatives commonly applied for reducing the size of the integrated circuits is the three-dimensional stack-type integrated circuits, which are obtained by stacking electronic chips vertically. Stacking multiple chips on top of each other can both increase the functionality of the integrated circuit and reduce the space requirements. However, as the size of transistors get smaller, the heat generated by the heat-generating electronic chips increases even more.

In stack-type integrated circuits, vertical interconnections and internal wire connections with solder bumps are widely used. The performance of the three-dimensional (3D) integrated circuits is significantly improved by fast and robust connections between the body surfaces. However, the connections used in stack-type integrated circuits packaged in this way prevent effective removal of the heat. In 3D stack-type integrated circuit technology, since the electronic chips are stacked on top of each other, the thermal paths to remove the heat generated by the chips are limited; therefore, the heat generated by the chips may not be sufficiently removed. In addition, as the number of the chips stacked increases, the resulting heating problem undoubtedly increases. Depending on an increase in ambient temperature, the performance of the transistor, and the reliability and durability of device are directly affected.

If the heat cannot be removed effectively in the integrated circuit systems, the temperature of the device remains above the critical level and the electrical properties of the integrated circuit system may deteriorate. As the number of chips increases in the stack-type integrated circuits, heat dissipation becomes more critical and challenging.

In view of the above, the cooling systems using a high heat flow are among the preferred thermal arrangements to keep the temperature of the electronic devices at the desired level.

Therefore, effective cooling systems are considered as one of the most important steps in the development of next generation integrated circuits.

In conventional semiconductor systems, some known methods of heat dissipation are as follows: cooling by air flow, cooling by a cooling fluid, cooling by auxiliary elements such as cooler and fan.

In cooling based on the use of coolers, a cooling element with a large surface area and including fins or a fan is mounted on the electronic circuit. The cooling devices aim to remove the heat of the integrated circuit, to which they are connected, from the environment. The thermal conductivity of the cooling device is one of the important characteristics that determine the effectiveness of this process. The heat removed from the electronic systems such as chips moves from the high temperature area to the lower temperature area through the cooler. However, due to the downsizing of the electronic devices, the use of such auxiliary cooling elements is not preferred. Because said additional auxiliary cooling elements cause an increase in the size of the electronic devices and an effective cooling cannot be achieved with the existing systems.

In another cooling method that can be implemented in smaller integrated circuits, there are available cooling fluid paths in contact with the electronic chips. A fluid passage that can provide cooling is provided through the said cooling fluid path. The most important problem in this method is the deterioration of the electrical properties of the electronic circuit over time as a result of the contact of the chip, which is an electronic system, with the cooling fluid. In addition, since the thermal resistance generated between the part where the cooling fluid flows and is in contact with, and the fluid, reduces the thermal conductivity, an effective heat transfer cannot be realized, thus the targeted cooling cannot be achieved.

In U.S. Pat. No. 6,055,154, a block with a high thermal conductivity is fixed on a circuit board, as a cooling system. The outer surface of the said block is in contact with the cooling fluid, but the fluid used herein has no contact with the chip. The cooling mechanism is such that the cooling fluid first cools the block, followed by the cooling of the electronic chip by the block.

Although the block used in U.S. Pat. No. 6,055,154 is used for cooling purposes, it cannot be incorporated into small-sized electronic systems.

U.S. Pat. No. 7,294,926 describes a cooling system of a semiconductor device comprising a chip area. According to the said document, a fluid channel with a fluid inlet and a fluid outlet extends through a portion of the chip area. Since the fluid channel is within the chip, the fluid has direct contact with the chip. In this case, short-circuit problems may occur due to the contact of the fluid and the chip.

In order to overcome the challenges above, there is a need in electronic circuits to effectively eliminate overheating problems that may adversely affect the performance of the devices, lead to the deterioration of the electrical properties and consequently the failure of the device.

### SUMMARY

### Objects of the Invention

Principal object of the present invention is to obtain a cooling system that allows the heat generated by the electronic chips used in electronic devices to be removed from the environment, thereby ensuring the cooling of the electronic chip.

Another object of the present invention is to effectively lower the surface temperature of the heated electronic chip.

Another object of the present invention is to ensure that the integrated circuits comprising electronic chips is capable of maintaining their electrical properties for a long period of time, thus improving the performance.

Another object of the present invention is to completely eliminate the chance of leakage that may arise from the cooling element in electronic devices in which electronic chips to be cooled are used.

Another object of the present invention is to integrate a low-cost cooling element into electronic chips, which is ease-to-manufacture and easy-to-use.

Another object of the present invention is to obtain a cooling system that does not cause an increase in the size of the integrated circuit systems to be used in electronic devices.

Another object of the present invention is to provide a cooling in which homogeneous distribution is achieved in the integrated circuit systems.

Still another object of the present invention is to provide a cooling system that can be directly integrated into existing systems, regardless of the number of electronic chips in the system.

The present invention describes an integrated circuit unit (11) comprising at least one electronic chip (10) consisting of a wafer body (1) with at least one groove (2) extending along its surface from one end to the other, and of an active area (5); said integrated circuit unit (11) further comprises at least one tube (3), which is housed in the groove (2) therein, and which allows the transport of a fluid for cooling the electronic chips (10).

The present invention also describes a three-dimensional stack-type integrated circuit system (12) comprising two integrated circuit units (11) and a three-dimensional stack-type integrated circuit system (12) comprising more than two integrated circuit units (11).

According to the present invention, there is described a method for obtaining said integrated circuit unit (11), comprising the steps of;
providing at least one electronic chip (10) consisting of a wafer body (1) and an active area (5),
forming at least one groove (2) extending from one end to the other along the surface of the wafer body (1) of the said electronic chip (10),
housing at least one tube (3) in the said groove (2).

According to the invention, at least one groove (2) is made in the wafer body (1) of the said electronic chip (10) directly by wet etching or dry etching method.

### BRIEF DESCRIPTION OF THE DRAWINGS

The integrated circuit unit which is the subject of the present invention is illustrated in the accompanying drawings for better understanding thereof, which drawings are attached for better explaining the present invention and are not limiting the invention, in which:

FIG. 1 is a side view of an integrated circuit unit comprising one electronic chip according to the present invention.

FIG. 2 is a three-dimensional stack-type integrated circuit system comprising two integrated circuit units according to the present invention.

FIG. 3A is a three-dimensional stack-type integrated circuit system comprising more than two integrated circuit units according to the present invention.

FIG. 3B shows the electrical connecting elements that enable the elements to communicate with each other in the three-dimensional stack-type integrated circuit system comprising more than two integrated circuit units according to the present invention.

FIGS. 4A, 4B show the different geometries of the grooves in the integrated circuit unit according to the present invention.

FIGS. 5A, 5B, 5D show the inlet and outlet configurations of the cooling fluid into/from the tubes in the integrated circuit unit according to the present invention.

FIGS. 5C, SE show the path which the cooling fluid in the tubes of the integrated circuit unit according to the present invention follows to exit the tube.

FIG. 6 shows the change of the temperature over time of the cooling fluid at the exit of the tube and the surface of the electronic chip in the system comprising the integrated circuit unit according to the present invention.

The invention will now be explained in detail with reference to the accompanying drawings, and the list of reference numerals used in the drawings is as follows.
1. Wafer body
2. Groove
3. Tube
4. Groove gap
5. Active area
6. Printed circuit board (PCB)
7. Primary solder ball
8. Connecting wire
9. Secondary solder ball
10. Electronic chip
11. Integrated circuit unit
12. Three-dimensional integrated circuit system
13. Fluid inlet
14. Fluid outlet
15. Covered hole extending through the thickness of the wafer
X, Y. Horizontal and vertical axis of the integrated circuit unit

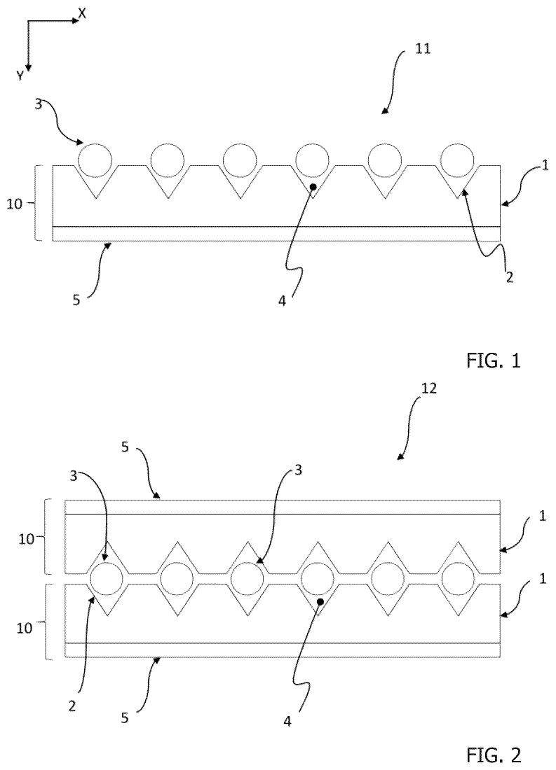

The same elements shown in the drawings are indicated separately in each figure. Where there is more than one identical element, the same one is numbered only once in each figure. For example, there are 6 tubes in FIG. 1, but, only one of them is numbered.

### DETAILED DESCRIPTION OF THE EMBODIMENTS

The present invention describes an integrated circuit unit (11) comprising at least one electronic chip (10) consisting of a wafer body (1) with at least one groove (2) extending along its surface from one end to the other, and of an active area (5), wherein there is provided at least one tube (3), which is housed in the said groove (2), and which allows the transport of a fluid for cooling the electronic chips (10). As can be seen in FIG. 1, the integrated circuit unit (11) described herein consists of only one electronic chip (10). Said electronic chip (10) consists of a wafer body (1) and an active area (5). By virtue of the groove made in the wafer body (1), it is understood that the grooves extend along the body of the electronic chip (10). The groove (2), which is made in the wafer body (1) and extends from one end to the other end of the surface of the wafer body, does not have to be in contact with the tube (3) housed therein. The outer wall of the tube (3) may be contact with the surface of the groove (2), or there may be a gap between said elements. In the case that the tube (3) and the surface of the groove (2) are not in contact, the gap therebetween is referred to the groove gap (4). The number of grooves made in the wafer body (1) can be varied. In addition, since the size of the electronic chip (10) that is desired to be cooled down will have an influence on how much heat will be generated, the number of grooves may vary according to the size of the electronic chip (10). The fluid is carried through each tube (3) in FIG. 1, thus, due to the cooling effect of the fluid, the excess heat in the electronic chip (10) is removed from the environment.

The electronic chips generate heat during the operation, which results in the heating of both the electronic chip itself and the neighboring circuit elements. If the generated heat cannot be removed quickly and efficiently, various problems are observed resulting from the overheating of the electronic devices having the electronic chips. With the present invention, a new cooling system is proposed to eliminate the heating problems that prevent the efficient operation of the electronic circuits. Accordingly, it is possible to cool the electronic chip (10), which consists of a wafer body (1) and an active area (5), by means of a cooling element incorporated into the same electronic chip (10). In this way, the need for another external cooling element for the electronic chip (10) is eliminated and sufficient cooling is provided without causing an increase in the size of the electronic circuits.

In the present invention, there is provided at least one groove (2) that is made in the wafer body (1) and extends along the surface of the wafer body (1) from one end to the other end of the said body. The number of grooves may vary depending on the dimensions of the electronic chip (10) and the cooling requirement. In the prior art, it is known to make a groove in the chip body. In such structures, the grooves are covered in order to create a closed area for the fluid to flow through the groove. Thus, a system is obtained which is based on fluid transfer. However, even if the grooves are covered with another element, the risk of leakage cannot be avoided. Because the fluid is in contact with the inner surface of the groove. Although the fluid passes through the groove (2), since it is in contact with the body of the electronic chip (10) during the cooling process, the cooling fluid may leak towards the active area (5) or other integrated circuit elements over time. Any leakages from any source in the electronic circuits cause the devices to short-circuit and eventually become inoperable. Therefore, in existing systems, even if cooling is provided by means of the fluid, undesirable results occur if the fluid moves to the neighboring circuit elements. At this point, it is inevitable that the fluid leaks towards the wafer body (1) of the electronic chip (10) and the active area (5), during the passage of thereof in the groove (2). To eliminate the problems arising from this system, the present invention proposes to use a tube (3) which is housed in the grooves (2) made in the wafer body (1) and extending on the surface of the wafer body (1), and which allows the transport of the fluid. With the tubes (3) inserted into the said grooves (2), the cooling fluid flows only inside the tube (3) without contacting any other circuit elements, and thus the risk of leakage is completely eliminated.

With the cooling fluid being in the tube (3), there is no need to support the electronic chip (10) with an external cooling element, so it can be easily applied in small-sized electronic systems. The cooling fluid and the tube (3) located in the groove (2) together can also be defined as a cooling element.

The cooling fluid is a material that passes through the tube (3) and helps to cool the electronic chip (10) as a result of the heat transfer in the environment. Thus, in the integrated circuit systems comprising one or more electronic chips (10), a cooling system based on fluid transfer is used.

On the other hand, since the cooling process in the system of the present invention takes place within the wafer body (1) of the electronic chips (10), the heat generated in the active area (5) of the electronic chips (10) is quickly removed from the environment without being concentrated in the area where it is generated. Thus, a significant increase in cooling performance is observed.

In another embodiment of the present invention, the grooves (2) in which the tubes (3) are housed extend parallel to the horizontal axis from one end of the wafer body (1) to the other.

According to another embodiment of the present invention, the cooling fluid carried in the tubes (3) does not contact the active area (5) of the electronic chip (10) and the wafer body (1). The only contact area of the fluid passing through the tubes (3), which are available in the grooves (2) as a separate element, is the inner walls of the tubes (3). Therefore, it is not possible for the fluid to leak into any part of the electronic chip (10), thus, the problem of short-circuit caused by the contact of the fluid is prevented. The tube housed in the groove (2) is structured to allow the transfer of the fluid. Thanks to the structure and geometry of the tube, the cooling fluid flowing along the electronic chip (10) and the wafer body (1) cannot get out of the tube (3). Thus, the communication of the fluid with the circuit elements and/or any part of the electronic chip (10) is prevented.

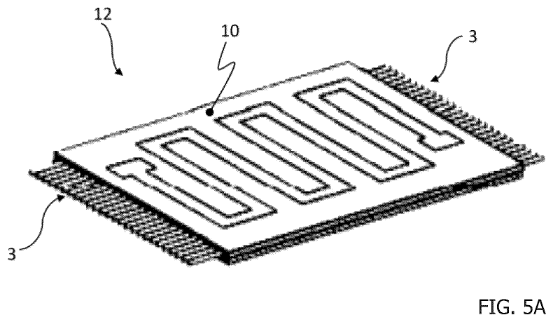

According to another embodiment of the present invention, the geometries of the grooves (2) on the surface of the wafer body (1) can be inverted pyramid, inverted trapezoidal, rectangular prism or cylindrical. For example, in FIGS. 4A and 4B, different geometries of the grooves (2) made in the wafer body (1) are shown.

In the integrated circuit unit (11) of the invention, the grooves (2) made in the wafer body (1) are obtained directly by wet etching or dry etching method. Without using a separate part, it has been more practical to form the grooves (2) directly on the wafer body (1). In this way, regardless of the number of electronic chips (10) in the integrated circuit system, a cooling system that can be directly integrated into existing systems has been obtained. The grooves made directly in the wafer body and the tubes housed therein are achieved more practically than the fluid channels that can alternatively be created in the wafer body. With the advantage in terms of cost, the tubes (3), which allow fluid to pass therethrough, are integrated with integrated circuit systems and used directly.

According to another embodiment of the present invention, the values of the groove width (W_{groove}) and the groove height (H_{groove}) can be determined according to the area to be cooled, the heat transfer and the cooling requirements, the thickness of the chip body, and the diameters of the external tubes that may be present.

According to another embodiment of the present invention, there may be coatings on the inner and/or outer surfaces of the tubes (3) in which the fluid that provides the cooling of the integrated circuit systems is contained and carried, which will increase the cooling performance. As another alternative, different structures can be integrated into the inner and/or outer surface of the said tubes (3).

The tubes (3) inserted into the grooves (2) formed on the surface of the wafer body (1) of the electronic chips (10) can be of any geometry. However, according to another embodiment of the present invention, there is no corner along the circumference of the said tubes (3). Preferably, circular tubes (3) are used to be housed in the groove (2) in the electronic chip (10) (FIG. 1). It has been observed that the cooling performance is improved by inserting the circular tubes (3) into the groove (2). The cooling performance is related to the velocity of the fluid in the tube (3). As the distance traveled by the cooling fluid per unit time increases, the amount of heat absorbed by the said fluid increases in direct proportion thereto. If the tube (3) through which the fluid flows has an angular inner wall such as a rectangle or triangle, the flow rate decreases and thus the convective heat transfer is negatively affected and the cooling performance decreases.

By the cooling fluid, it is meant the fluids that flow in the tube (3) and ensure the cooling of the electronic chip (10) by transferring the heat of the electronic chip (10) towards itself, due to its low temperature.

According to another embodiment of the present invention, the cooling fluid conveyed in the said tube (3) may be a dielectric liquid. The use of a dielectric liquid has eliminated the risk of short circuit. If liquid is used in the tube (3) instead of air, the amount of the heat transmitted from the active area (5) of the hotter electronic chip (10) to the liquid in the colder tube (3) increases significantly. Since the main purpose is to cool the electronic chip (10), i.e., it is aimed at achieving a heat transfer from the hot environment to the cold environment, it is desired that said heat transfer takes place at the maximum level. Therefore, it is desired that the cooling fluid to pass through the tube (3) is a dielectric liquid. In another preferred embodiment, water can be used as the cooling fluid.

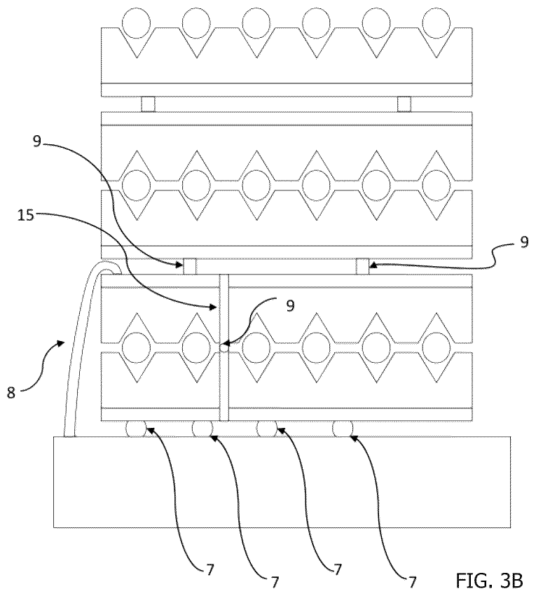

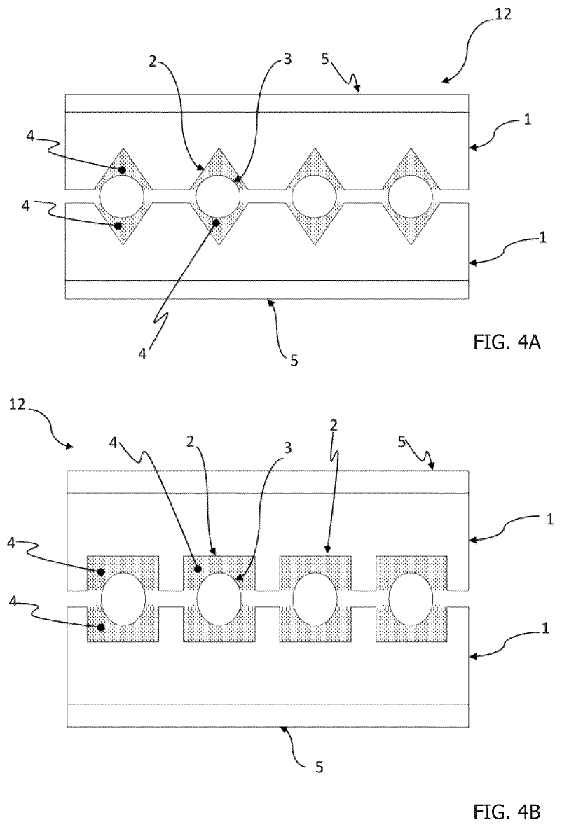

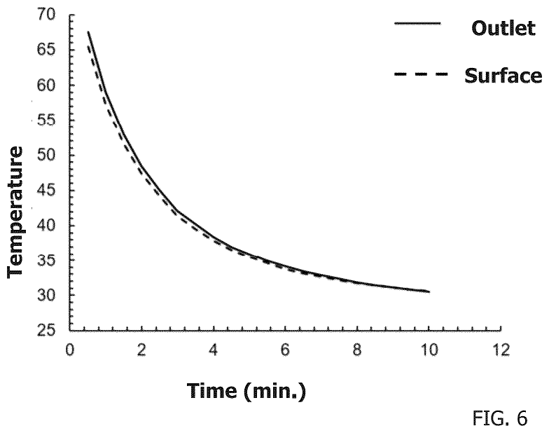

According to another embodiment of the present invention, there is provided a thermal conductive material in the groove (2) where the tube (3) is placed (FIG. 3A, FIG. 4A, FIG. 4B). The groove gap (4) in the groove (2) of the wafer body (1) can be partially or completely filled with a thermal conductive material. As shown in FIGS. 4A and 4B, the surface of the grooves (2) formed on the surface of the wafer body (1) and the outer walls of the tubes (3) in the groove gap (4) do not contact each other, and the groove gaps (4) are filled with a thermally conductive material. The thermally conductive material may also be present in such a way to surround the outside of the tube (3) through which the flow of the cooling fluid is enabled. With the use of a thermally conductive material, the performance of the heat transfer between the cooling fluid in the tube (3) and the active area (5) and the wafer body (1) of the electronic chip (10), which are desired to be cooled, is increased. One of the drawbacks in the heat transfer mechanisms is the situations caused by thermal resistance. As the thermal resistance increases, the resistance of the materials against the heat transfer increases. In the present invention, since the electronic chip (10) is intended to be cooled, it is expected to ensure maximum heat transfer to transfer the heat in the heated areas. At the points where thermal resistance is observed, heat transfer cannot be achieved at the desired level. On the other hand, in addition to cooling of the electronic chip (10), it is desirable that the difference between the temperature of the cooling fluid and the temperature of the chip surface is minimal. The fact that the temperature of the cooling fluid and the temperature of the chip surface are close to each other indicates that maximum heat transfer is provided, and maximum heat is transferred from the hot chip surface, which is the hot portion, to the cooling fluid part, which is the colder portion. In this case, it is understood that in addition to the cooling of the overall electronic chip (10), the chip surface is also cooled at the maximum level. As can be seen in FIG. 6, it has been observed that the temperature of the tube (3) at the exit point and the temperature of the surface of the electronic chip (10) are the same in the integrated circuit system where fluid passage is allowed for a certain period of time. According to FIG. 6, the temperature of the surface of the electronic chip (10), which was 65° C. before the cooling process, is decreased to 30° C. in 10 minutes. In the system wherein a temperature decrease of 35° C. is provided in 10 minutes, the fact that the temperature at the fluid outlet and the temperature on the surface of the electronic chip are equal at the end of the specified time indicates that the cooling performance is at the maximum level.

If the tubes (3) through which the cooling fluid flows are only housed in the grooves (2) in the wafer body (1) of the electronic chips (10), without putting any material thereto, then thermal resistance is observed. To eliminate this problem, the gap in the grooves (2) is partially or completely filled with a thermal conductive material. Since the thermal conductive material is present in the groove (2) and acts as a bridge between the tube (3) and the electronic chip (10), the thermal resistance problem is prevented. Thus, a greater amount of heat flows towards the tube (3) containing the cooling fluid.

In another preferred embodiment of the present invention, the thermal conductivity coefficient of the material in the gap inside the groove (2) can be in the range of 50 W/m·K and 75 W/m·K. Preferably, a thermal paste can be used as a thermally conductive material.

According to another embodiment of the present invention, the wafer body (1) of the electronic chip (10) can be made of a semiconductor material. Silicon, gallium arsenide (GaAs), gallium nitride (GaN), indium phosphate (InP), silicon germanium (SiGe), quartz or glass can be used as the material of the wafer body (1). Silicon is preferably used as the material of the wafer body.

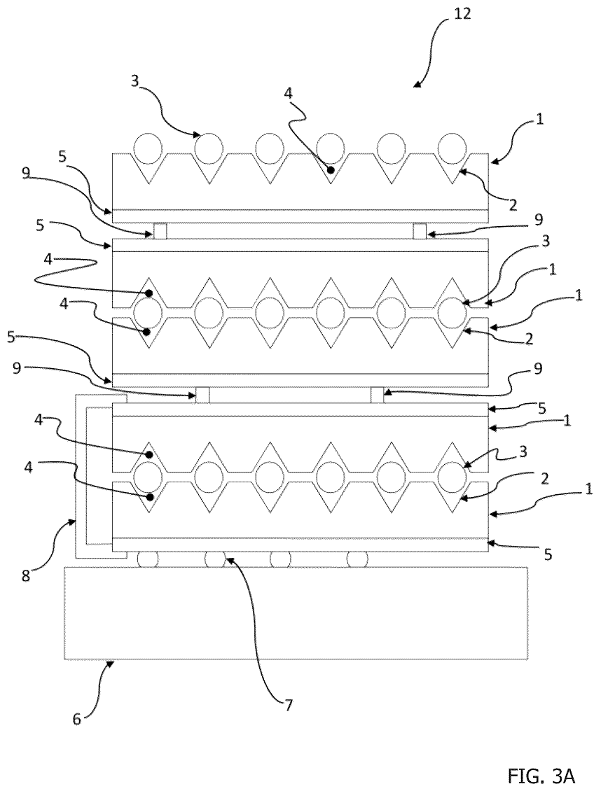

The system proposed by the present invention aims to cool the electronic chips (10). The housing of the tubes (3) in the grooves (2) on the surface of the wafer body (1) of the invention can be implemented in the integrated circuit units (11) comprising a single electronic chip (10), as well as the three-dimensional stack-type integrated circuits systems (12) comprising more than one electronic chip (10) (FIG. 2, FIG. 3A).

In the integrated circuit unit (11), there is provided at least one electronic chip (10), preferably one electronic chip (10), and furthermore, there may be different circuit elements that are required to function in the electronic device.

By the “three-dimensional stack-type integrated circuit system (12)”, it is meant the systems comprising at least two electronic chips (10) (FIG. 2, FIG. 3A). The wafer bodies (1) of the said electronic chips (10) are positioned to face each other. The important thing here is that there is provided at least one groove (2) in the wafer body (1) of the electronic chips (10) and that there is provided at least one tube (3) in the groove (2) that allows the passage of the cooling fluid.

Referring to FIG. 2, in the three-dimensional stack-type integrated circuit system (12), which consists of two integrated circuit units (11) comprising two electronic chips (10), there is provided at least one groove (2) in the wafer body (1) of each electronic chip (10), and there are provided tubes (3) inserted into each groove (2). In the case where two electronic chips (10) are used, at least a part of the electronic chips (10) is aligned to be opposite to each other. Here, the wafer bodies (1) of the electronic chips (10) face each other. The grooves (2) on the surface of the wafer body (1) of each electronic chip (10) are in such a way as to allow the tube (3) to be housed therein, and at least a part of the said grooves (2) is aligned with each other. In this case, the grooves (2) that are opposite to each other form a housing form and the tubes (3) for performing the transfer of cooling fluid are placed into the housing slots. After the said tubes (3) are housed therein, the groove gaps (4) remaining in the grooves (2) can be filled with a thermally conductive material.

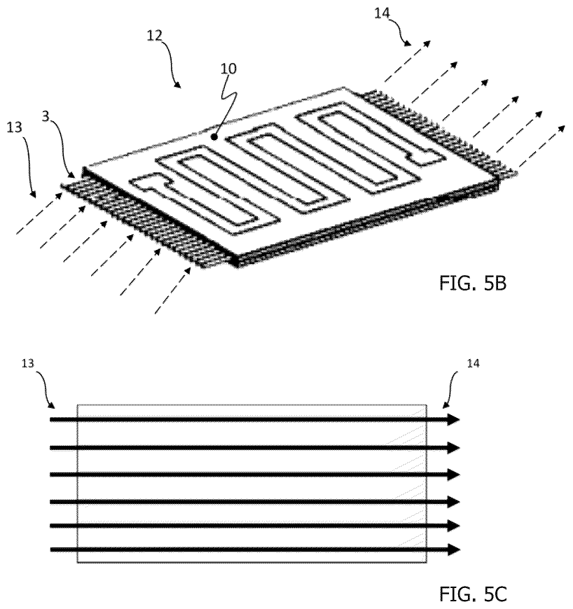

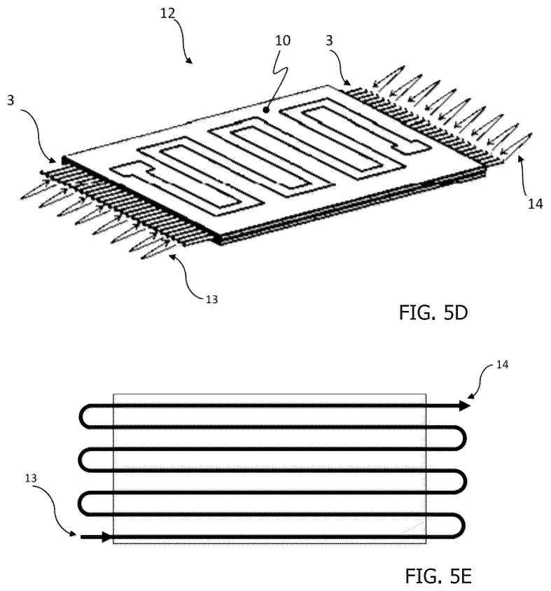

In the three-dimensional stack-type integrated circuit system (12) shown in FIGS. 5A, 5B, 5C, 5D, SE, there are provided the tubes (3) carrying fluid therethrough to remove the excess heat generated within the two electronic chips (10). The tubes (3), which are in the grooves (2) extending along the wafer bodies (1) of the electronic chips (10), are located between the electronic chips (10) in the stack-type integrated circuit system.

In the three-dimensional stack-type integrated circuit system (12) shown in FIG. 5B, a fluid inlet (13) is provided from one end of each tube (3). The fluid that enters the tubes (3) separately moves along the wafer body (1) inside the tube (3), and there is a fluid outlet (14) at the point where the tube (3) ends. In this case, a separate fluid outlet is observed from each tube (3) and the fluid moves through parallel tubes independent from each other. (FIG. 5C).

In the three-dimensional stack-type integrated circuit system (12) shown in FIG. 5D, the tubes (3) are likewise housed in the grooves (2) in the wafer body (1), and since two electronic chips (10) are placed on top of each other, the tubes (3) remained between the electronic chips (10). Here, the fluid entering from one or more tubes on the same side of the electronic chip circulates through other tubes and proceeds in its path, and exits through one or more tubes on the other side of the electronic chip. According to the fluid passage shown in detail FIG. 5E, there is a fluid inlet (13) from one end of the tube, and there occurs a fluid outlet (14) from the tube, in which the path thereof is completed by circulating through the other tubes, respectively. Accordingly, the tube from which the fluid enters and exits may not be the same. Also, the fluid inlet is from an end of the tube on one side of the electronic chip, while the fluid outlet is from an end of the tube on the other side of the electronic chip (FIG. 5D, SE).

The integrated circuit unit (11) according to the present invention is also applied in three-dimensional stack-type integrated circuit systems (12) comprising more than two electronic chips (10). In stack-type integrated circuit systems, since the electronic chips (10) are positioned on top of each other, it is much more difficult to remove the heat generated by the electronic chips (10), when compared to the heat removal in systems comprising one electronic chip (10) As the number of electronic chips increases, the amount of heat generated also increases, so it is more difficult to remove this heat from the environment. In the case of using a single cooling element, the cooling of the electronic chips (10) adjacent to the cooling element is achieved, but the electronic chips (10) located further away cannot be sufficiently cooled. At this point, due to the presence of grooves (2) in the wafer body (1) of each electronic chip (10) and the tubes (3) allowing the transfer of the cooling fluid in the grooves (2), as proposed by the present invention, the heat generated in each electronic chip (10) is removed from the environment by the cooling element therein. In this way, both effective cooling is achieved and the risk of leakage is eliminated by means of the tube structure inside the groove (2). In the three-dimensional stack-type integrated circuit system (12), there is no limitation on the number of electronic chips, and a desired number of electronic chips (10) can be used according to the needs of the electronic device. As shown in FIG. 3A, in the three-dimensional stack-type integrated circuit systems (12), each electronic chip (10) is first positioned such that the wafer bodies (1) face each other. In this case, another electronic chip (10) is positioned opposite to each electronic chip (10). The electronic chips (10) prepared in pairs with the wafer bodies (1) facing each other are then connected to each other by electrical connecting elements in such a way that all of the electronic chips (10) are on top of each other, and thus a three-dimensional stack-type integrated circuit system (12) is formed. In this system, there is at least one groove (2) in the wafer body (1) of each electronic chip (10), and there are tubes (3) inside the said grooves (2) that allow the passage of the cooling fluid.

At least one connecting wire (8) and at least one primary and/or secondary solder ball (7), (9) can be used in order to connect the electronic chips (10) to each other and/or to connect the electronic chips and the printed circuit board to each other. The covered hole (15) extending through the thickness of the wafer, in which there is provided at least one secondary solder ball (9), enables the connection of the electronic chips (10). The connecting wire (8) can also provide a connection from the edge ends of the electronic chips (10), in which case the lower electronic chip will be wider than the upper one. The stack of the electronic chips is placed on a printed circuit board (PCB) (6) by way of at least one primary solder ball (7).

All the said configurations for the integrated circuits comprising one electronic chip (10) according to the invention are applicable to entire systems comprising two or more electronic chips (10).

In the method performed to form an integrated circuit unit (11) according to the present invention, the following steps are performed:
providing at least one electronic chip (10) consisting of a wafer body (1) and an active area (5),
forming at least one groove (2) extending from one end to the other along the surface of the wafer body (1) of the said electronic chip (10),
housing at least one tube (3) in the said groove (2).

According to another embodiment of the present invention, wet etching or dry etching methods can be applied directly to form grooves (2) on the surface of the wafer body (1) of the electronic chips (10). In other words, the grooves (2) in which the tubes (3) that will ensure the transfer of the cooling fluid are located, are formed directly inside the electronic chip (10) to be cooled. Thus, the production process is easier and an advantage is provided in terms of cost.

According to another embodiment of the present invention, the housing of the tubes (3), allowing the transfer of the cooling fluid, into the grooves (2) can be carried out by any method. The tubes (3) can be inserted into the grooves (2) manually or by means of a micromanipulator.

According to the present invention, the tubes (3) within the electronic chip (10) ensure the transfer of the cooling fluid. The cooling fluid flowing through the tubes (3) ensures that the undesirable excess heat generated in the electronic chip (10) is removed from the environment. While the passage of the cooling fluid through the electronic chip (10) takes place through the tubes (3), the inlet and outlet mechanisms to the tubes (3) can be arranged by any system. A central cooling system ensures that the cooling fluid reaches the entry point of the tubes (3). The cooling system transfers the fluid to be used for cooling to the entry point of the tubes (3) with a suitable method. The cooling fluid, which reaches the entry point of the tubes (3), then proceeds in its path along the electronic chip (10) that is desired to be cooled, while absorbing the heat generated in the chip so as to cool the electronic chip. The cooling fluid, which completes its path inside the electronic chip (10), leaves the electronic chip (10) at the exit point of the tube (3) and returns to the cooling system.

In the system of the present invention, the circulation of the cooling fluid may be carried out by active means using equipment such as a pump, or by passive means using a device such as a water heater.

1. An integrated circuit unit comprising:
at least one electronic chip consisting of a wafer body with at least one groove extending along its surface from one end to the other, and of an active area, wherein
the integrated circuit unit further comprises at least one tube, which is housed in the at least one groove, and which allows a transport of a cooling fluid for cooling the at least one electronic chips.

2. The integrated circuit unit according to claim 1, wherein the at least one groove extend parallel to each other along a horizontal axis of the wafer body.

3. The integrated circuit unit according to claim 1, wherein the at least one tube is configured not to allow the cooling fluid carried therein to contact with an active area and the wafer body of the at least one electronic chip, and configured to allow only the fluid transfer.

4. The integrated circuit unit according to claim 1, wherein a geometry of the at least one groove is in the shape of inverted pyramid, inverted trapezoid, rectangular prism or cylindrical.

5. The integrated circuit unit according to claim 1, wherein the integrated circuit comprises the at least one groove obtained on the wafer body directly by wet etching or dry etching method.

6. The integrated circuit unit according to claim 1, wherein the at least one tube has a form that does not include any corners along its circumference, preferably a circular form.

7. The integrated circuit unit according to claim 1, wherein the cooling fluid carried in the at least one tube is dielectric liquid.

8. The integrated circuit unit according to claim 7, wherein the dielectric liquid is water.

9. The integrated circuit unit according to claim 1, wherein a thermal conductive material is provided in the at least one groove where the at least one tube is placed.

10. The integrated circuit unit according to claim 9, wherein the gap in the at least one groove contains, partially or completely, a thermal conductive material.

11. The integrated circuit unit according to claim 9, wherein the thermal conductivity coefficient of the said thermal conductive material is in the range of 50-75 W/m·K.

12. The integrated circuit unit according to claim 9, wherein the thermal conductive material is a thermal paste.

13. The integrated circuit unit according to claim 1, wherein the wafer body is made of a semiconductor material, preferably silicon.

14. A three-dimensional stack-type integrated circuit system comprising two of the integrated circuit units according to claim 1.

15. The three-dimensional stack-type integrated circuit system according to claim 14, comprising two electronic chips with at least a part of which is aligned opposite to each other and the wafer bodies face each other, wherein each electronic chip has grooves on the surfaces of the wafer body, at least a part of which is aligned opposite to each other, and the grooves are configured to allow the at least one tube to be housed therein.

16. A three-dimensional stack-type integrated circuit system comprising more than two of the integrated circuit units according to claim 1.

17. A method for forming the integrated circuit unit according to claim 1, comprising the steps of:
providing at least one electronic chip consisting of a wafer body and an active area,
forming at least one groove extending from one end to the other along the surface of the wafer body of the at least one electronic chip, and
housing the at least one tube in the groove.

18. The method according to claim 17, wherein the at least one groove is made in the wafer body of the at least one electronic chip directly by wet etching or dry etching method.

19. The integrated circuit unit according to claim 2, wherein the at least one tube is configured not to allow the cooling fluid carried therein to contact with an active area and the wafer body of the at least one electronic chip, and configured to allow only the fluid transfer.

20. The integrated circuit unit according to claim 2, wherein a geometry of the at least one groove is in the shape of inverted pyramid, inverted trapezoid, rectangular prism or cylindrical.
